(19) United States
(12) Patent Application Publication
(10) Pub. No.: US 2026/0313954 A1
(43) Pub. Date: Oct. 8, 2026

(54) PLANAR MOSFET HAVING ASYMMETRIC WELLS

(71) Applicant: Microchip Technology Incorporated, Chandler, AZ (US)

(72) Inventors: Shesh Mani Pandey, Gilbert, AZ (US); Bruce Odekirk, Portland, OR (US)

(73) Assignee: Microchip Technology Incorporated, Chandler, AZ (US)

(21) Appl. No.: 19/250,550

(22) Filed: Jun. 26, 2025

Related U.S. Application Data
(60) Provisional application No. 63/784,676, filed on Apr. 7, 2025.

(51) Int. Cl. H10D 30/66; H10D 30/01; H10D 62/10; H10D 62/60

(52) U.S. Cl. CPC H10D 30/66; H10D 62/102; H10D 62/124; H10D 62/60; H10D 30/0291

(57) ABSTRACT

A semiconductor device comprising: a volume of semiconductor material including an opposite bottom spaced from the top, a first side, and an opposite second side spaced from the first side; a source positioned along the top; a drift region having a first charge carrier polarity; a well having a second charge carrier polarity that is opposite the first charge carrier polarity and forming a well junction with the drift region; and a second region adjacent the well and forming a second region junction with the drift region. The second region junction is nearer the bottom and nearer the second side of the volume of semiconductor material than the well junction.

### CROSS-REFERENCE TO RELATED APPLICATIONS

The current patent application claims the benefit under 35 U.S.C. § 119(e) of the priority date of U.S. Provisional Application Ser. No. 63/784,676 titled “PLANAR MOSFET HAVING ASYMMETRIC WELLS” and filed Apr. 7, 2025. The Provisional Application is hereby incorporated by reference, in its entirety, into the current patent application.

### TECHNICAL FIELD

The present disclosure relates to metal oxide semiconductor field-effect transistors (MOSFETs) and methods of making them. More particularly, the various examples described herein concern a planar MOSFET having asymmetric wells, and a method of making same.

### BACKGROUND

A MOSFET is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, choppers, and more. It is generally desirable to improve the performance and to reduce the cost of MOSFETs, but it can be difficult to do so.

This background discussion is intended to provide related information, and is not necessarily prior art, or exhaustive.

### SUMMARY

In an example, a semiconductor device, such as a MOSFET, may include a volume of semiconductor material. The volume of semiconductor material may include a top, an opposite bottom spaced (e.g., vertically) from the top, a first side, and an opposite second side spaced (e.g., horizontally, or laterally) from the first side. The semiconductor device may also include: a source positioned along the top; a drift region having a first charge carrier polarity; a well having a second charge carrier polarity opposite the first charge carrier polarity; and a second region adjacent the well having the second charge carrier polarity. The well may extend from the first side of the volume of semiconductor material and form a well junction with the drift region. The second region may form a second region junction with the drift region. The second region junction may be both nearer the bottom and nearer the second side than the well junction.

In a second example, a semiconductor device, such as a MOSFET, may include a volume of semiconductor material. The volume of semiconductor material may include a top, an opposite bottom spaced (e.g., vertically) from the top, a first side, and an opposite second side spaced (e.g., horizontally, or laterally) from the first side. The semiconductor device may also include: a source positioned along the top; a drift region having a first charge carrier polarity; a well having a second charge carrier polarity opposite the first charge carrier polarity; and a second region adjacent the well having the second charge carrier polarity. The well may extend from the first side of the volume of semiconductor material and form a well junction with the drift region. The second region may form a second region junction with the drift region. The second region junction may be nearer the bottom than the well junction, and a portion of the drift region may be positioned between the second region and the top.

This summary is not intended to identify essential features of examples, and is not intended to be used to limit the scope of the claims. These and other aspects of the present examples are described below in greater detail.

### BRIEF DESCRIPTION OF THE DRAWINGS

Examples are described in detail below with reference to included drawing figures, wherein:

FIG. 1a illustrates an example planar MOSFET having a first pair of asymmetric wells;

FIG. 1b illustrates an example planar MOSFET having a second pair of asymmetric wells;

FIG. 2 illustrates an example method for making a planar MOSFET having asymmetric wells, in accordance with the present disclosure;

FIG. 3a illustrates the planar MOSFET of FIG. 1b following formation of a volume of semiconductor material and a portion of a second region;

FIG. 3b illustrates the planar MOSFET of FIG. 3a following formation of a second portion of the second region;

FIG. 4 illustrates the planar MOSFET of FIG. 3b following addition of well segments to complete the pair of asymmetric wells of FIG. 1b;

FIG. 5 illustrates the planar MOSFET of FIG. 4 following formation of sources and drains;

FIG. 6 illustrates the planar MOSFET of FIG. 5 following deposition of dielectric and polysilicon layers;

FIG. 7 illustrates the planar MOSFET of FIG. 6 following etching of the dielectric and polysilicon layers; and

FIG. 8 illustrates the planar MOSFET of FIG. 7 following a metallization step.

The figures are not intended to limit the examples to the specific details depicted therein. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

Terms of relative location and direction (e.g., above, below, left, right, upper, lower, vertical, horizontal, lateral, and the like) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Broadly, examples presented herein physically and functionally integrate asymmetric wells into a planar semiconductor device and describe methods for making semiconductor devices including such asymmetric wells. Examples advantageously provide the benefit(s) of increased device performance due to lower gate-drain capacitance (C_{gd}), decreased drain-induced barrier lowering (DIBL), reduced drain-source “ON” resistance (R_{dson}), and increased short-circuit withstand time (SCWT) while also reducing manufacturing costs.

Various examples described herein are broadly directed to a planar semiconductor device, such as a MOSFET, that includes asymmetric first and second wells. The asymmetry between the first and second wells may at least in part be attributable to a second region (discussed in more detail below) included within the semiconductor device that is positioned, or formed, adjacent, and optionally as a portion of, the first well during the manufacturing process. According to the present disclosure, the second region may be contiguous with and have a substantially similar dopant concentration as the remainder of the first well.

Each of the first and second wells may be positioned along the “top” of the semiconductor device on the respective first or second side of the volume of semiconductor material. First and second sources may respectively be positioned adjacent to the first and second wells. A gate may also be positioned at the top of the device. The gate may be positioned between the first and second wells so that a portion of the gate is overlapping at least a portion of each of the first and second wells and each of the first and second sources. The second region underlying the gate and, optionally, the second well may enhance the performance of the semiconductor device by one or more of: lowering C_{gd}, decreasing DIBL, reducing R_{dson}, or increasing SCWT.

The second region may extend into a drift region of the semiconductor device, toward the second well. As described further herein, various shapes, sizes, and positions of the second region relative to the first well are permissible under the present disclosure.

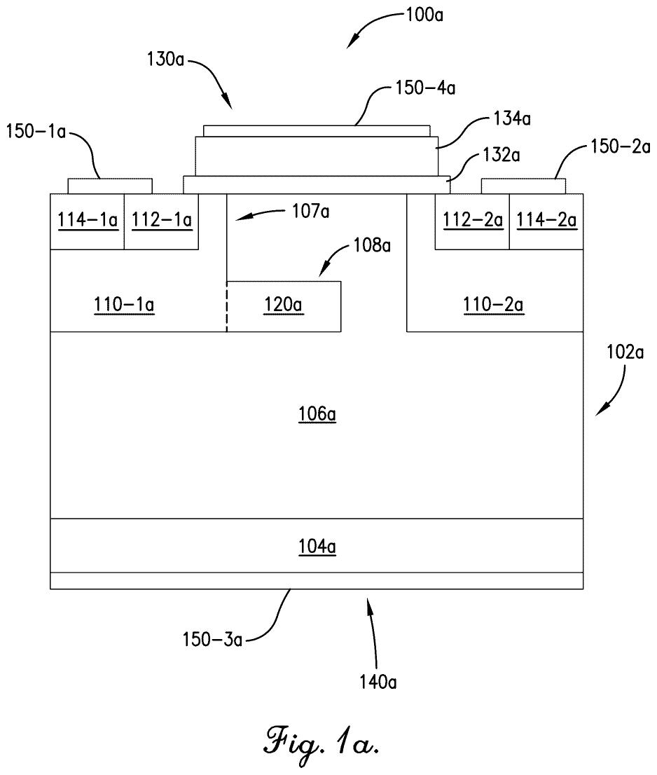

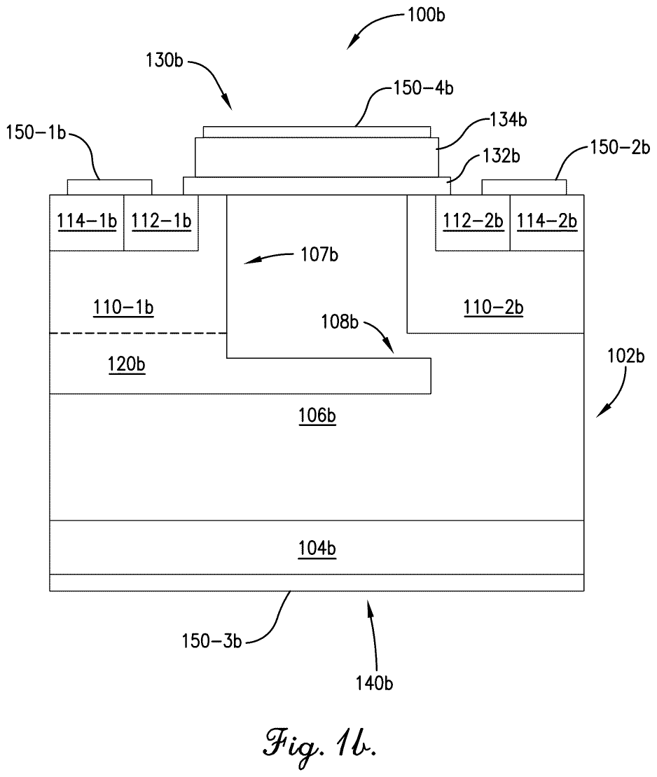

Referring to FIG. 1a, an example of a semiconductor device 100a having asymmetric wells is shown. The semiconductor device 100a may be formed from a volume of semiconductor material 102a, which may be formed on a substrate 104a. The semiconductor device 100a may be a silicon (Si) or silicon carbide (SiC) device, although other material compositions of the semiconductor device 100a are within the scope of the present disclosure.

The semiconductor device may include a drift region 106a, a first well 110-1a, a second well 110-2a, a first source 112-1a, a second source 112-2a, a first body 114-1a, a second body 114-2a, a second region 120a, a gate 130a, and a drain 140a.

The volume of semiconductor material 102a may be formed, e.g., via epitaxial growth, or otherwise provided on the substrate 104a, which may also be epitaxially grown, or otherwise provided. The volume of semiconductor material 102a may include a top, an opposite bottom spaced (e.g., vertically) from the top, a first side, and a second side spaced (e.g., laterally, or horizontally) from the first side. The volume of semiconductor material 102a may comprise, or be formed of, an N-type material. The substrate 104a may comprise, or be formed of, an N+ material.

Broadly, the drift region 106a is a region of semiconductor device 100a through which current flows between sources 112-1a, 112-2a, and drain 140a. According to examples of the present disclosure, the drift region 106a occupies the volume of semiconductor material 102a other than the first well 110-1a, the second well 110-2a, the first source 112-1a, the second source 112-2a, the first body 114-1a, the second body 114-2a, and the second region 120a. The drift region 106a may have a first charge carrier polarity. The drift region 106a may comprise, or be formed from, an N-type material, and therefore have a negative charge polarity. In various examples, a portion of the drift region 106a may be positioned between the second region 120a and the top along a vertical axis.

The first well 110-1a may extend from the first side of the volume of semiconductor material 102, and form a well junction 107a with the drift region 106a. The first well 110-1a may have a second charge carrier polarity that is opposite the first charge carrier polarity (e.g., a positive charge polarity). A “junction,” as used herein, accordingly refers to the boundary between regions respectively comprising positive and negative charge polarities. The first well 110-1a may comprise, or be formed from, a P-type material. The first well 110-1a and other regions of the volume of semiconductor material 102a may be formed via ion implantation, or any other suitable technique.

The second region 120a may be formed/positioned adjacent to the first well 110-1a. The second region 120a may have the second charge carrier polarity that is opposite the first charge carrier polarity (e.g., a positive charge polarity). The second region 120a may be contiguous with and have a substantially similar dopant concentration as the first well 110-1a, resulting in the second region 120a being effectively (e.g., physically and/or functionally) integrated into the first well 110-1a. However, for illustrative purposes, a dashed line has been used to delineate between the second region 120a and the first well 110-1a.

The second region 120a may comprise, or be formed from, a P-type material. The second region 120a may form a second region junction 108a with the drift region 106a. As illustrated in FIG. 1a, the second region junction 108a may be nearer the bottom than the well junction 107a. The second region junction 108a may also be nearer the second side of the volume of semiconductor material 102a than the well junction 107a. It will be appreciated that any portion of the junction between the second region 120a and the drift region 106a (e.g., any portion of the perimeter of the second region 120a that is outlined with a solid line in FIG. 1a) may be considered the second region junction 108a.

According to the present disclosure: the first well 110-1a may include a lateral extent, or portion, measured from the first side to a portion of the well junction 107a that is nearest the second side; the second region 120a may have a lateral extent, or portion, measured from the first side to a portion of the second region junction 108a that is nearest the second side; and the lateral extent of the second region 120a may be at least ten percent (10%) greater than the lateral extent of the first well 110-1a. The lateral extent of the second region 120a may be at least five percent (5%), twenty percent (20%), twenty-five percent (25%), thirty percent (30%) or fifty percent (50%) greater than the lateral extent of the first well 110-1a.

The first source 112-1a may be positioned along the top of the volume of semiconductor material 102a and adjacent to at least a portion of the first well 110-1a, and the first body 114-1a may be positioned adjacent to the first source 112-1a. Generally, a source (e.g., the first source 112-1a) comprises, or is formed from, a semiconductor material (e.g., Si or SiC) and charge carriers (e.g., electrons or holes, depending on the material composition of the source) flow from or toward the source and, correspondingly, toward or from a drain (e.g., the drain 140a). A body (e.g., the first body 114-1a), when connected to a source (e.g., the first source 112-1a) may help maintain a stable threshold voltage (V_{T}) within/across a semiconductor device (e.g., the semiconductor device 100a) to ensure proper function of the device. In various examples, the first source 112-1a may comprise, or be formed from, an N+ material, and the first body 114-1a may comprise, or be formed from, a P+ material.

The semiconductor device 100a further includes the second well 110-2a, extending from the second side. The second well 110-2a may have the second charge polarity. Accordingly, the second well 110-2a may comprise, or be formed from, a P-type material. The second well 110-2a may form a second well junction with the drift region 106a. The second well junction may be any portion of the P-N junction between the second well 110-2a and the drift region 106a (e.g., as represented by the solid line delineating between the second well 110-2a and the drift region 106a).

In various examples (such as those in accordance with the semiconductor device 100a of FIG. 1a), a vertical extent, or portion of the second region 120a may be equivalent to a vertical extent of the second well 110-2a. In such examples, one or more portions of a bottom side of the second region 120a may be co-planar with one or more portions of a bottom side of the second well 110-2a. In these examples, at least a portion of a second region junction 108a is also co-planar with the one or more portions of the bottom side of each of the wells 110-1a, 110-2a. Further, a portion of the second region 120a underlies and is spaced below a portion of gate 130a such that at least a portion of the drift region 106a is positioned therebetween. A portion of the drift region 106a is also interposed or positioned between the second region 120a and the second well 110-2a.

In various other examples (e.g., those in accordance with the semiconductor device 100b of FIG. 1b), the vertical extent, measured along the vertical axis from the top, of the second region 120b may be greater than that of the second well 110-2b, with the second region 120b extending closer to the bottom of the semiconductor device 100b than the second well 110-2b. As depicted in FIG. 1b, at least a portion of the drift region 106b is positioned between the second region 120b and the top of the semiconductor device 100b, seen along the vertical axis. A portion of the drift region 106b is also interposed or positioned between the second region 120b and the second well 110-2b. In these and similar examples, the vertical extent of the second region 120b may be, for instance, five percent (5%), ten percent (10%), twenty percent (20%), thirty percent (30%), forty percent (40%), or fifty percent (50%), without limitation, greater than the vertical extent of the second well 110-2b.

One of ordinary skill will appreciate that a second region may take a variety of shapes within the scope of the present disclosure. In various examples, however, such shapes satisfy the following: (i) bottom sides of each of a first well, a second region, and a second well are co-planar; (ii) the second region does not extend vertically all the way to the top of a volume of semiconductor material; (iii) the second region does not extend laterally all the way to the second well; and (iv) the second region does not get depleted when the semiconductor device is used.

Other shapes are permissible, however, such as where the bottom sides of each of a first well, a second region, and a second well are not co-planar, as illustrated in FIG. 1b. Accordingly, and as illustrated in FIG. 1b, at least a portion of the second region 120b may be nearer the bottom of the volume of semiconductor device 102b than the second well 110-2b.

Referring again to FIG. 1a, the second source 112-2a is positioned adjacent to the second well 110-2a. The second source 112-2a may be positioned along the top of the volume of semiconductor material 102a and adjacent to at least a portion of the second well 110-2a, and a second body 114-2a may be positioned adjacent to the second source 112-2a. The second source 112-2a may comprise, or be formed from, an N+ material, and the second body 114-2a may comprise, or be formed from, a P+ material.

The first source 112-1a and the second source 112-2a may comprise separate, distinct (e.g., single-ended) sources, or they may be two sides or contacts of the same source or electrode (e.g., the first source and second source 112-1a, 112-2a may, at some point not depicted in FIG. 1a, combine into a single-ended source).

The gate 130a may include a layer of dielectric material 132a, or gate oxide (e.g., silicon dioxide [SiO₂]) and a layer of polysilicon material 134a positioned above the layer of dielectric material 132a. As depicted in FIG. 1a, the gate 130a may be positioned along the top of the semiconductor device 100a and over, or above, at least a portion of each of the first well 110-1a, the first source 112-1a, the second well 110-2a, and the second source 112-2a.

The drain 140a may be positioned along the bottom of the volume of semiconductor material 102a, and may be contiguous with or included in the substrate 104a. The drain 140a may comprise, or be formed from, an N+ material. Current that flows through the semiconductor device 100a may traverse from the first source 112-1a and/or the second source 112-2a into at least a portion of the drain 140a.

The semiconductor device 100a may further include electrical terminals, or contacts, 150-1a through 150-4a to facilitate the application of various electrical signals thereto. More specifically, first and second electrical terminals 150-1a, 150-2a, may be added to the first source 112-1a and the second source 112-2a, respectively. A third electrical terminal 150-3a may be applied to the drain 140a, which may be a single, contiguous terminal. A fourth electrical terminal 150-4a may be applied to the gate 130a (e.g., on top of the polysilicon layer 134a).

In operation, when a gate-source voltage (V_{gs}) is applied between the source terminals 150-1a, 150-2a, and the gate terminal 150-4a, the generated electric field creates an inversion layer at the semiconductor-dielectric interface. The inversion layer may provide a channel(s) (not shown in FIG. 1a) through which electrical current can flow when a drain-source voltage (V_{ds}) is applied between the source terminals 150-1a, 150-2a and the drain terminal 150-3a. More specifically, V_{gs} controls the width of the depletion region at the P-N junction where the charge carriers of the P- and N-type materials diffuse into each other, which depletes the available concentration(s) of majority charge carrier in each material, thereby controlling a current (I_{d}) that flows between the drain 140a and one or more of the sources 112-1a, 112-2a. According to the present disclosure, the second region 120a may vary in area and/or dopant concentration provided there are a sufficient number of charge carriers included therein that the second region 120a does not substantially deplete during operation of the semiconductor device (e.g., when V_{gs} and V_{ds} are applied).

Referring to FIG. 1b, semiconductor device 100b includes asymmetric wells (e.g., wells 110-1b, 110-2b) is shown. The semiconductor device 100b of FIG. 1b may be substantially similar, or identical to the semiconductor device depicted 100a of FIG. 1a, except for the geometry and/or position of the second region 120b within the volume of semiconductor material 102b and corresponding changes to the geometry and/or position of the first well 110-1b and drift region 106b, including corresponding junctions.

As in FIG. 1a, the second region 120b of FIG. 1b may be effectively integrated (e.g., contiguous with and of a substantially similar or identical dopant concentration) with the first well 110-1b. Therefore, the dashed line located between the second region 120b and the first well 110-1b may, in various examples, be considerable as a purely imaginary boundary. One of ordinary skill will appreciate, however, that other examples may include second regions which are discontinuous with and/or have different characteristics than the first well (e.g., different dopant concentrations), and/or which are implanted or otherwise formed in different operations and/or using different apparatus, within the scope of the present disclosure.

As seen in FIG. 1b, at least a portion of a top side of the second region 120b may be adjacent to/abutting a portion of a bottom side of the first well 110-1b. Again, the second region 120b has a greater vertical extent relative to second well 110-2b, measured from the top, than the second region 120a relative to its second well 110-2a. Further, the second region 120b may extend toward the second side of the volume of semiconductor material 102b to such a degree that it matches or exceeds the lateral extent (measured along the horizontal axis from the first side) of the gate 130b. The second region 120b may also or alternatively underlie or overlap (e.g., at a vertical remove) the second well 110-2b, as illustrated in FIG. 1b. As noted above, however, a second region may not underlie or overlap a second well (for example, the second region may stop short of extending below the second well) within the scope of the present disclosure. As a result, a portion of the drift region 106b is positioned between the laterally extending portion of the second region 120b and the second well 110-2b.

Similar to FIG. 1a, the semiconductor device 100b of FIG. 1b includes a well junction 107b, formed between the first well 110-1b and the drift region 106b, along with a second region junction 108b formed between the second region 120b and the drift region 106b. The well junction 107b depicted in FIG. 1b may include any portion of the P-N junction that exists between the first well 110-1b and the drift region 106b. The second region junction 108b depicted in FIG. 1b may include any portion of the P-N junction that exists between the second region 120b and the drift region 106b.

Material composition and/or dimensions (e.g., vertical depth and lateral width) of the sub-components/features depicted in the semiconductor device 100b illustrated in FIG. 1b (e.g., the first well 110-1b, the second well 110-2b, the first body 114-1b, the second source 112-2b, etc.) may be substantially similar or identical to the equivalent sub-component/feature of the semiconductor device 100a depicted in FIG. 1a (e.g., the first well 110-1a of FIG. 1a may be of substantially similar size and/or material composition as the first well 110-1b of FIG. 1b), except as otherwise described above and illustrated in the drawings. However, it will be appreciated that different proportions and material compositions for any combination of the sub-components/features discussed above may be within the scope of the present disclosure.

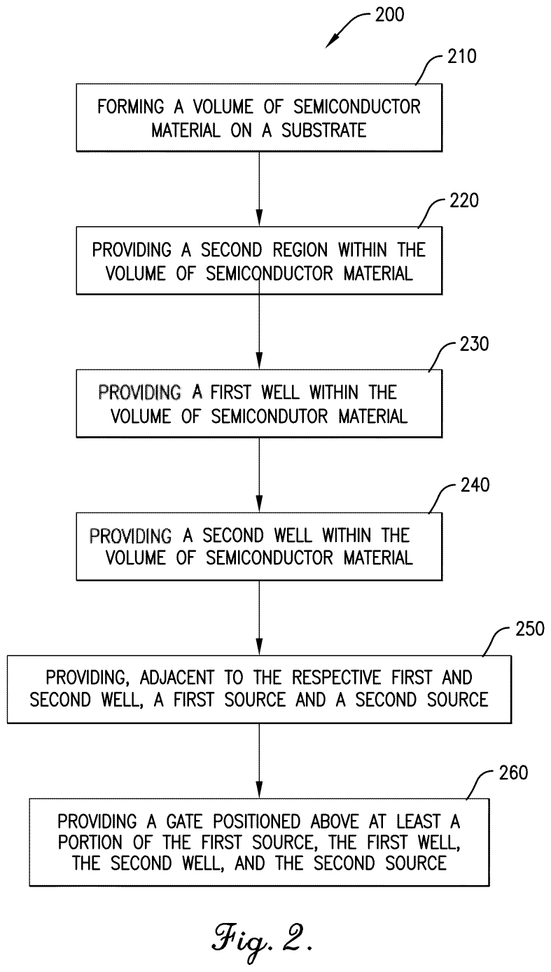

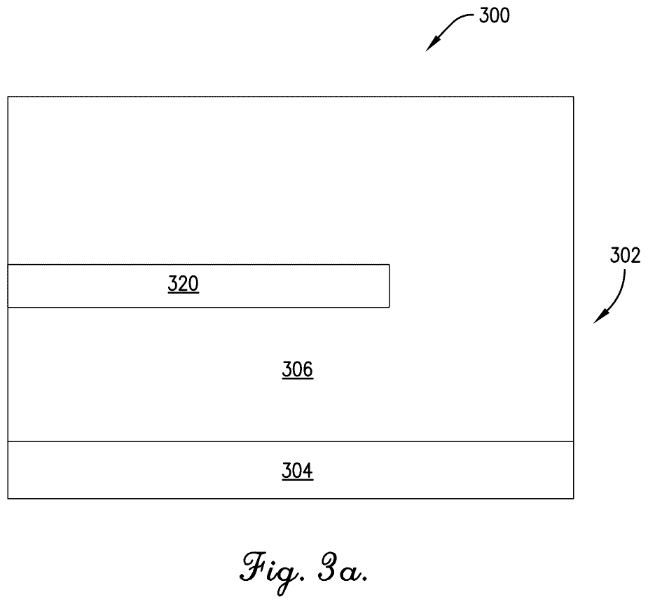

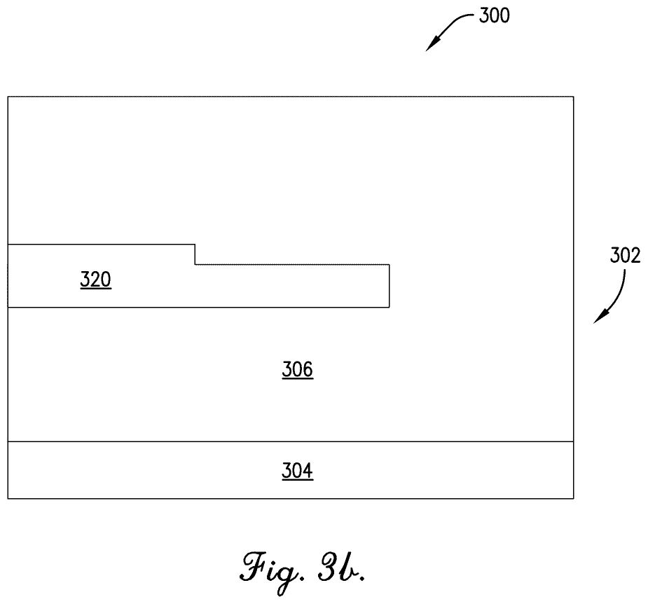

FIG. 2 depicts a method 200 for forming a semiconductor device, such as a planar MOSFET, having asymmetric wells. The operations may be performed in the order shown in FIG. 2, or the operations may be performed in a different order. Furthermore, some operations may be performed concurrently as opposed to sequentially. In addition, some operations may be optional. Reference is also made to FIGS. 3-8 showing the results of certain of the operations of the method 200. The device (e.g., the semiconductor device 300 of FIGS. 3-8, to be described in more detail below) formed via the method 200 and any sub-components (e.g., a drain 340, a gate 330, a first well 310-1, a second source 312-2, a drift region 306, etc.) included therein may be substantially similar or identical to the semiconductor device 100b, or the equivalent, corresponding sub-component (e.g., the drain 140b, the gate 130b, the first well 110-1b, the second source 112-2b, the drift region 106b, etc.) of FIG. 1b. However, it will be appreciated that the method 200 may be used to form the semiconductor device 100a depicted in FIG. 1a, as well as numerous other semiconductor devices including wells having various other asymmetries not depicted/described throughout this disclosure.

Broadly, any feature, portion, area, or volume (doped or undoped) of a semiconductor device formed via the method 200 may be formed via any process suitable to forming said features, portion, area, or volume. For instance, ion implantation and other similar/suitable processes may be used to form wells, sources, bodies, and the like, without limitation. Epitaxial growth and similar/suitable processes may be used to form substrates and initial volumes of semiconductor material. Etching and other similar/suitable processes may be used to remove select portions of the semiconductor material once formed (e.g., to form a trench within the volume of semiconductor material) or to remove portions of oxide, metal or metal alloy layers, without limitation. Deposition and other similar/suitable processes may be used to fill trenches once etched, to form electrical terminals (or contacts), or the like, without limitation.

At operation 210, the method 200 of forming a semiconductor device 300 includes forming, or otherwise providing, on a substrate 304, a volume of semiconductor material 302. The volume of semiconductor material 302 may include a top, an opposite bottom spaced (e.g., vertically) from the top, a first side, and an opposite second side spaced (e.g., laterally) from the first side. The volume of semiconductor material 302 may further include a drift region 306 having a first charge polarity.

The substrate 304 may be epitaxially grown, or otherwise provided, and may comprise or be formed of a N+ material. The volume of semiconductor material 302 may be grown, e.g., epitaxially, on the substrate 304 once the substrate 304 has been formed/provided. The volume of semiconductor material 302 as initially formed (e.g., prior to the formation or implantation of the second region 320 and other wells, sources, bodies, or the like formed within the volume of semiconductor material 302 as described above and below), and therefore the drift region 306, may comprise or be formed of an N-type material.

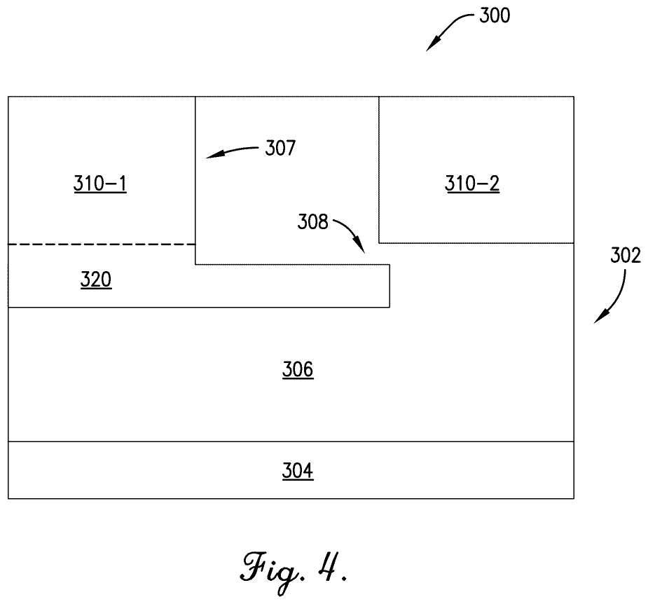

At operation 220, a second region 320 having a second charge carrier polarity opposite the first charge carrier polarity may be provided, or formed, within the volume of semiconductor material 302. The second region 320 may form a second region junction 308 (see FIG. 4) with the drift region 306, and a portion of the drift region 306 may be positioned between the second region 320 and the top, seen along a vertical axis.

As illustrated in FIGS. 3a and 3b, the second region 320 may be formed in multiple stages. For example, formation of a portion of the second region 320 at a greater vertical depth within the volume of semiconductor material 302 (as measured from the top) is illustrated in FIG. 3a. In FIG. 3b, an upper segment of the second region 320 is formed, which will be substantially laterally coextensive with the first well 310-1 (see FIG. 4). Despite the possibility of staged formation, the second region 320 may, in various examples, be a single, continuous volume. Similarly, and as noted above, the second region 320 may also be a single, continuous and contiguous volume with the first well 310-1. In various examples, it may be preferable for the second region 320 to comprise, or be formed of, a P-type material, although other material compositions of the second region 320 may be permissible. Ion implantation or any other suitable process, or any combination of processes, may be used to form the second region 320.

At operation 230, a first well 310-1 having the second charge carrier polarity may be formed or otherwise provided within the volume of semiconductor material 302. The first well 310-1 may also comprise or be formed, e.g., via ion implantation, of P-type material. The first well 310-1 may extend from the first side of the volume of semiconductor 302, and form a well junction 307 with the drift region 306. In various examples, at least a portion of the second region junction 308 may be nearer the bottom and the second side of the volume of semiconductor material 302 than the well junction 307.

The well junction 307 and the second region junction 308 depicted in FIGS. 4-8 may be substantially similar or identical to the corresponding well junction 107b and second region junction 108b of FIG. 1b. However, in various examples (not illustrated), the well junction 307 and second region junction 308 may alternatively be formed to be substantially similar or identical to the corresponding well junction 107a and second region junction 108a of FIG. 1a.

The first well 310-1 may be provided/formed adjacent to the second region 320 and have a substantially similar or identical material composition and/or dopant concentration as the second region 320. Accordingly, the well first 310-1 and the second region 320 may, effectively, be one continuous region within the volume of semiconductor material 302. As in FIGS. 1a and 1b, the dashed line used in FIGS. 4-8 to delineate between the first well 310-1 and the second region 320 is purely a visual aid for distinguishing between the two (2) regions. However, it is foreseen that the regions may be distinguished by differing dopant concentrations or the like without departing from the spirit of the present disclosure.

At operation 240, a second well 310-2 having the second charge polarity may be formed, or otherwise provided, within the volume of semiconductor material 302. The second well 310-2 may extend from the second side of the volume of semiconductor material 302. Like the first well 310-1, the second well 310-2 may comprise or be formed of a P-type material. Ion implantation or any other suitable process may be used to form the second well 310-2. The wells 310-1 and 310-2 may be formed simultaneously and/or as part of the same operation. In various examples, it may be preferable for the wells 310-1 and 310-2 to have the same dimensions (e.g., vertical depth and lateral width within the volume of semiconductor material 302). A fully formed first well 310-1 and second well 310-2 can be seen in FIG. 4.

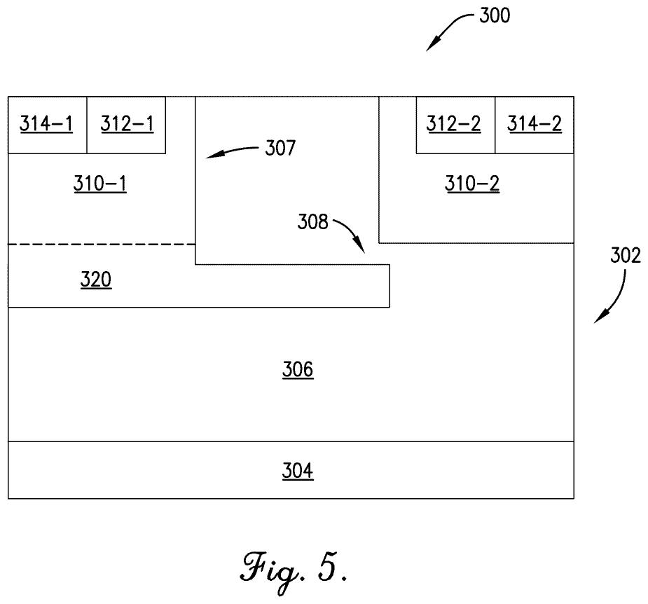

At operation 250, as depicted in FIG. 5, a first source 312-1 and a second source 312-2 may be provided along the top of the volume of the semiconductor material 302. The first source 312-1 may be adjacent to the first well 310-1 and the second source 312-2 may be adjacent to the second well 310-2. Each of the sources 312-1, 312-2 may comprise or be formed of a N+ material, and each of the sources 312-1, 312-2 may be provided via ion implantation or any other suitable process. A first body 314-1 and a second body 314-2 may be formed adjacent to the first source 312-1 and the second source 312-2, respectively. Each of the bodies 314-1, 314-2 may comprise or be formed of a P+ material, and each of the bodies 314-1, 314-2 may be formed via ion implantation, or by any other suitable process.

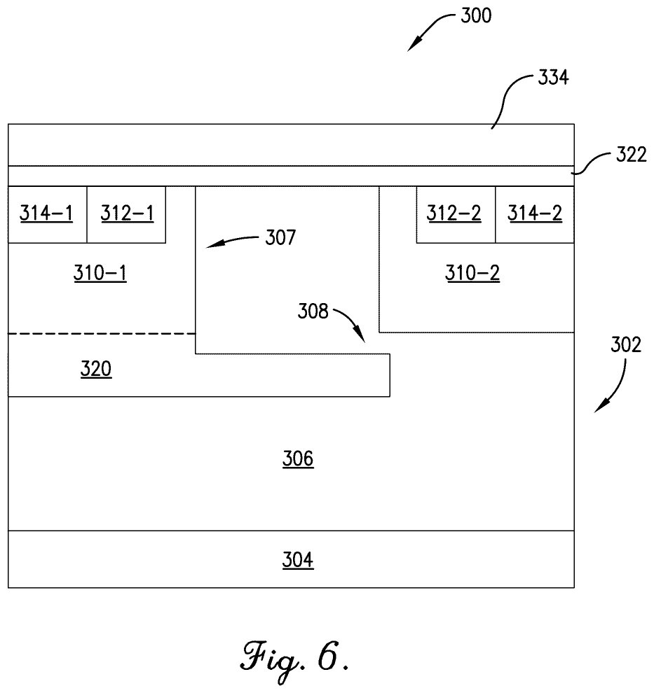

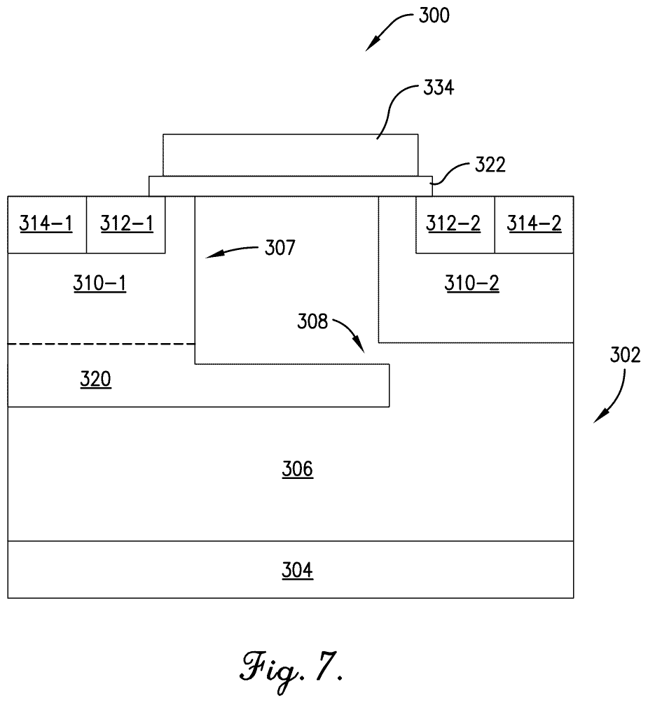

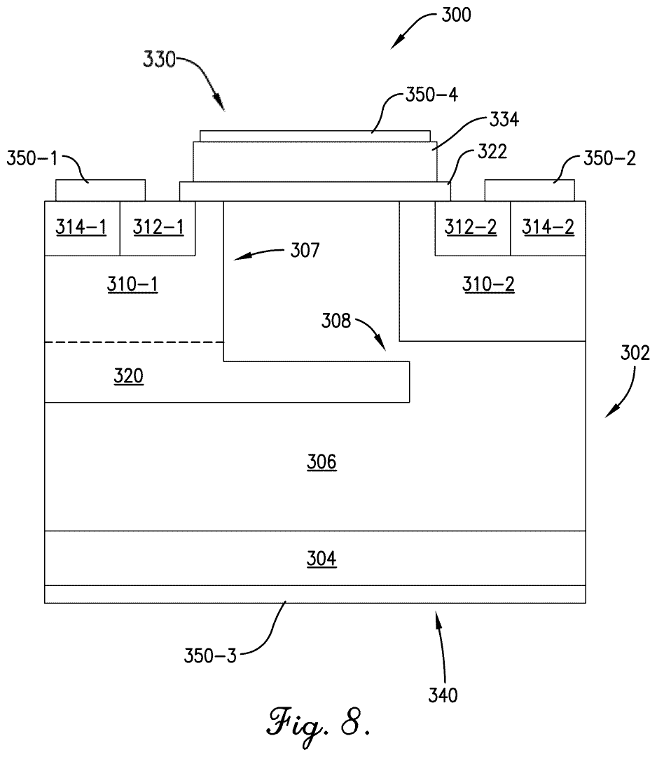

At operation 260, as depicted in FIGS. 6 and 7, a dielectric layer 332 and a layer of polysilicon material 334 above the dielectric layer 332 are provided along the top of the volume of semiconductor material 302. When combined with an electric terminal (e.g., the electric terminal 350-4 of FIG. 8), the dielectric layer 332, the layer of polysilicon material 334, and the electric terminal 350-4 may collectively form gate 330 (e.g., as seen in FIG. 8).

Initially, as depicted in FIG. 6, the dielectric layer 332 and the layer of polysilicon material 334 may span the entire lateral width of the volume of semiconductor material 302. As seen in FIG. 7, a portion of each of the dielectric layer 332 and the layer of polysilicon material 334 may be etched away, or otherwise removed, from each of the first and second sides of the volume of semiconductor material 302. As depicted in FIG. 7, the dielectric layer 332 is positioned on top of the volume of semiconductor material 302, extending between and partly overlying each of the wells 310-1, 310-2. The dielectric layer 332 is positioned adjacent to/above at least a portion of each of the first source 312-1, the first well 310-1, the second well 310-2, and the second source 312-2. The lateral width of layer of polysilicon material 334 may be less than that of the layer of dielectric material 332 after the etching/removal operation.

FIG. 8 depicts the semiconductor device 300 after a “metallization” operation, during which electrical terminals 350-1, 350-2, 350-3, and 350-4 are respectively formed on the first source 312-1, the second source 312-2, the substrate 304, and the layer of polysilicon material 334. As mentioned above, the gate 330 comprises the electrical terminal 350-4, the layer of polysilicon material 334, and the dielectric layer 332. Similarly, the drain 340 includes the substrate 304 and the electrical terminal 350-3. Also as explained above, adding the electrical terminals 350-1 through 350-4 facilitates application of electrical signals to the semiconductor device 300.

Additional processing may be performed as desired.

Additional details regarding the method 200 and the intermediate operations thereof depicted in FIGS. 3-8 can be found in the description of FIGS. 1a and 1b above.

### Feature Combinations

According to various examples of the present disclosure, a semiconductor device may comprise: a volume of semiconductor material including a top, an opposite bottom spaced from the top, a first side, and an opposite second side spaced from the first side; a source positioned along the top; a drift region having a first charge carrier polarity; a well having a second charge carrier polarity opposite the first charge carrier polarity, the well extending from the first side and forming a well junction with the drift region; and a second region adjacent the well having the second charge carrier polarity, the second region forming a second region junction with the drift region, the second region junction being nearer the bottom than the well junction, and the second region junction being nearer the second side of the volume of semiconductor material than the well junction.

In combination with any of the previous examples, the second region may be contiguous with and have a substantially similarity dopant concentration as the well.

In combination with any of the previous examples, a portion of the drift region may be positioned between the second region and the top.

In combination with any of the previous examples, a drain may be positioned along the bottom.

In combination with any of the previous examples, the well may have a lateral extent measured from the first side to a portion of the well junction that is nearest the second side, the second region may have a lateral extent measured from the first side to a portion of the second region junction that is nearest the second side, and the lateral extent of the second region may be at least ten percent (10%) greater than the lateral extent of the well.

In combination with any of the previous examples, the semiconductor device may further include a second well extending from the second side, the second well having the second charge carrier polarity.

In combination with any of the previous examples, at least a portion of the second region may be nearer the bottom than any portion of a second well.

In combination with any of the previous examples, a second well may form a second well junction with the drift region, the second well may have a vertical extent measured from the top to a portion of the second well junction that is nearest the bottom, the second region may have a vertical extent measured from the top to a portion of the second region junction that is nearest the bottom, and the vertical extent of the second region may be at least ten percent (10%) greater than the vertical extent of the second well.

In combination with any of the previous examples, the source may be positioned adjacent the well, and the semiconductor device may further include a second source positioned along the top adjacent a second well and a drain positioned along the bottom.

In combination with any of the previous examples, the well may comprise a P-type material, the drift region may comprise an N-type material, the second region may comprise a P-type material, and the source may comprise an N+ material.

### General Considerations

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

The methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

Although described herein with regard or in relation to one or more particular kinds of electronic devices (e.g., junction field-effect transistor, metal oxide semiconductor field-effect transistor), the technology may be more broadly applicable to one or more other kinds of electronic devices as well.

One with ordinary skill in the art will recognize that the technology described herein may, when applicable, be implemented in enhancement mode or depletion mode.

Further, the technology described herein may, when applicable, be implemented as an N-channel or P-channel device, wherein, in general, regions that are N-doped or P-doped in N-channel implementations may be, respectively, P-doped or N-doped in P-channel implementations.

Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide (Al₂O₃), hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }8 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17.

Relatedly, a structure or region may contain two or more different doping doses. For example, one with ordinary skill in the art will recognize that some P-wells may contain a lower dose P-well portion and a higher dose unclamped inductive switching portion.

What is claimed is:

1. A semiconductor device comprising:
a volume of semiconductor material including a top, an opposite bottom spaced from the top, a first side, and an opposite second side spaced from the first side;
a source positioned along the top;
a drift region having a first charge carrier polarity;
a well having a second charge carrier polarity opposite the first charge carrier polarity, the well extending from the first side and forming a well junction with the drift region; and
a second region adjacent the well having the second charge carrier polarity, the second region forming a second region junction with the drift region, the second region junction being nearer the bottom than the well junction, and the second region junction being nearer the second side of the volume of semiconductor material than the well junction.

2. The semiconductor device of claim 1, the second region being contiguous with, and having a substantially similar dopant concentration as, the well.

3. The semiconductor device of claim 1, wherein a portion of the drift region is positioned between the second region and the top.

4. The semiconductor device of claim 1, further comprising a drain positioned along the bottom.

5. The semiconductor device of claim 1,
the well having a lateral extent extending laterally from the first side to a portion of the well junction that is nearest the second side,
the second region having a lateral extent extending laterally from the first side to a portion of the second region junction that is nearest the second side, and
the lateral extent of the second region being at least ten percent (10%) greater than the lateral extent of the well.

6. The semiconductor device of claim 1, further comprising a second well extending from the second side and having the second charge carrier polarity.

7. The semiconductor device of claim 6, wherein at least a portion of the second region is nearer to the bottom than any portion of the second well.

8. The semiconductor device of claim 7,
the second well forming a second well junction with the drift region,
the second well having a vertical extent extending vertically from the top to a portion of the second well junction that is nearest the bottom,
the second region having a vertical extent extending vertically from the top to a portion of the second region junction that is nearest the bottom, and
the vertical extent of the second region being at least ten percent (10%) greater than the vertical extent of the second well.

9. The semiconductor device of claim 6, wherein the source is positioned adjacent the well, further comprising a second source positioned along the top adjacent the second well and a drain positioned along the bottom.

10. The semiconductor device of claim 1, wherein:
the well comprises a P-type material,
the drift region comprises an N-type material,
the second region comprises a P-type material, and
the source comprises an N+ material.

11. A semiconductor device comprising:
a volume of semiconductor material including a top, an opposite bottom spaced from the top, a first side, and an opposite second side spaced from the first side;
a source positioned along the top;
a drift region having a first charge carrier polarity;
a well having a second charge carrier polarity opposite the first charge carrier polarity, the well extending from the first side and forming a well junction with the drift region; and
a second region adjacent the well having the second charge carrier polarity, the second region forming a second region junction with the drift region, the second region junction being nearer the bottom than the well junction, and a portion of the drift region being positioned between the second region and the top.

12. The semiconductor device of claim 11, the second region being contiguous with, and having a substantially similar dopant concentration as, the well.

13. The semiconductor device of claim 11, further comprising a drain positioned along the bottom.

14. The semiconductor device of claim 11,
the well having a lateral extent extending laterally from the first side to a portion of the well junction that is nearest the second side,
the second region having a lateral extent extending laterally from the first side to a portion of the second region junction that is nearest the second side, and
the lateral extent of the second region being at least ten percent (10%) greater than the lateral extent of the well.

15. The semiconductor device of claim 11, further comprising a second well extending from the second side and having the second charge carrier polarity.

16. The semiconductor device of claim 15, wherein a portion of the second region underlies and is spaced apart from the second well.

17. The semiconductor device of claim 15, wherein at least a portion of the second region is nearer to the bottom than any portion of the second well.

18. The semiconductor device of claim 17,
the second well forming a second well junction with the drift region,
the second well having a vertical extent extending vertically from the top to a portion of the second well junction that is nearest the bottom,
the second region having a vertical extent extending vertically from the top to a portion of the second region junction that is nearest the bottom, and
the vertical extent of the second region being at least ten percent (10%) greater than the vertical extent of the second well.

19. The semiconductor device of claim 15, wherein the source is positioned adjacent the well, further comprising a second source positioned along the top adjacent the second well and a drain positioned along the bottom.

20. The semiconductor device of claim 1, wherein:
the well comprises a P-type material,
the drift region comprises an N-type material,
the second region comprises a P-type material, and
the source comprises an N+ material.
